(19) United States
(12) Patent Application Publication
(10) Pub. No.: US 2014/0077387 A1
(43) Pub. Date: Mar. 20, 2014

(54) SEMICONDUCTOR PACKAGE AND FABRICATION METHOD THEREOF

(71) Applicant: SILICONWARE PRECISION INDUSTRIES CO., LTD., Taichung Hsien (TW)

(72) Inventors: Kuan-Wei Chuang, Taichung Hsien (TW); Chun-Tang Lin, Taichung Hsien (TW); Yi-Chian Liao, Taichung Hsien (TW); Yi Che Lai, Taichung Hsien (TW)

(73) Assignee: SILICONWARE PRECISION INDUSTRIES CO., LTD., Taichung Hsien (TW)

(21) Appl. No.: 13/682,103

(22) Filed: Nov. 20, 2012

(30) Foreign Application Priority Data
Sep. 17, 2012 (TW) 101133934

(51) Int. Cl. H01L 23/48; H01L 21/50

(52) U.S. Cl. CPC H01L 23/481; H01L 21/50
USPC 257/774; 438/113

(57) ABSTRACT

A fabrication method of a semiconductor package is provided, which includes the steps of: cutting a substrate into a plurality of interposers; disposing the interposers on a carrier, wherein the interposers are spaced from one another by a distance; disposing at least a semiconductor element on each of the interposers; forming an encapsulant to encapsulate the interposers and the semiconductor elements; and removing the carrier. Therefore, by cutting the substrate first, good interposers can be selected and rearranged such that finished packages can be prevented from being wasted due to inferior interposers.

### BACKGROUND OF THE INVENTION

1. Field of the Invention

The present invention relates to semiconductor packages, and more particularly, to a semiconductor package having through silicon vias (TSVs) and a fabrication method thereof.

2. Description of Related Art

Flip-chip technologies facilitate to reduce chip packaging sizes and shorten signal transmission paths and therefore have been widely used for chip packaging. Various types of packages such as chip scale packages (CSPs), direct chip attached (DCA) packages and multi-chip module (MCM) packages can be achieved through flip-chip technologies.

In a flip-chip packaging process, a big CTE (Coefficient of Thermal Expansion) mismatch between a chip and a packaging substrate adversely affects the formation of joints between conductive bumps of the chip and contacts of the packaging substrate, thus easily resulting in delamination of the conductive bumps from the packaging substrate. On the other hand, along with increased integration of integrated circuits, a CIE mismatch between a chip and a packaging substrate induces more thermal stresses and leads to more serious warpage, thereby reducing the product reliability and resulting in failure of a reliability test.

To overcome the above-described drawbacks, a silicon interposer is disposed between a semiconductor chip and a packaging substrate. Since the silicon interposer and the semiconductor chip are made of similar materials, the above-described drawbacks caused by a CTE mismatch can be effectively prevented.

FIGS. 1A to 1C are schematic cross-sectional views showing a fabrication method of a semiconductor package 1 according to the prior art.

Referring to FIG. 1A, a plurality of TSVs 100 are formed in a silicon interposer 10, and an RDL (Redistribution Layer) structure (not shown) is formed on an upper side of the silicon interposer 10. Then, a plurality of semiconductor chips 11 are disposed on the upper side of the silicon interposer 10 and electrically connected to the TSVs 100 through a plurality of conductive bumps 110.

Referring to FIG. 1B, an encapsulant 12 is formed on the silicon interposer 10 for encapsulating the semiconductor chips 11, thereby forming a plurality of packages 1a.

Referring to FIG. 1C, an RDL structure 13 is formed on a lower side of the silicon interposer 10 according to the practical need and subsequently a singulation process is performed to obtain a plurality of singulated packages 1a. Such a singulated package 1a is then disposed on and electrically connected to a packaging substrate 15 through a plurality of conductive bumps 14.

However, forming the through silicon vias 100 in the silicon interposer 10 results in a high fabrication cost. Further, after a semiconductor wafer is singulated into a plurality of semiconductor chips 11, good semiconductor chip 11 can be selected through an electrical performance test and further disposed on the silicon interposer 10. However, according to the process yield, some units 10′ of the silicon interposer 10 may be inferior. As such, a good semiconductor chip 11 may be disposed on an inferior unit 10′. Therefore, the finished package 1a cannot pass a reliability test and consequently the good semiconductor chip 11 must be wasted along with the inferior unit 10′, thereby increasing the fabrication cost.

On the other hand, if inferior units 10′ are detected before forming the encapuslant 12 so as to avoid disposing of good semiconductor chips 11 on the inferior units 10′, it will become difficult to control the amount and flow path of the encapsulant 12. Consequently, the semiconductor chips 11 cannot be evenly covered by the encapsulant 12.

In addition, since the silicon interposer 10 is not singulated before disposing the semiconductor chips 11, the semiconductor chips 11 are required to be less in size than the corresponding units 10′, thereby limiting the number of the electrodes of the semiconductor chips 11. Consequently, the module function and efficiency of the units 10′ are limited.

Therefore, how to overcome the above-described drawbacks has become urgent.

### SUMMARY OF THE INVENTION

In view of the above-described drawbacks, the present invention provides a semiconductor package, which comprises: an interposer having opposite first and second surfaces and side surfaces connecting the opposite first and second surfaces, and a plurality of conductive through holes penetrating the first and second surfaces, wherein each of the conductive through holes has a first end exposed from the first surface and a second end opposite to the first end; a semiconductor element disposed on the first surface of the interposer; and an encapsulant encapsulating the interposer and the semiconductor element in a manner that the sides surfaces of the interposer are covered by the encapsulant.

The present invention further provides a fabrication method of a semiconductor package, which comprises the steps of: providing a substrate having opposite first and second surfaces and a plurality of conductive through holes penetrating the first surface, wherein each of the conductive through holes has a first end exposed from the first surface and a second end opposite to the first end; cutting the substrate into a plurality of interposers, wherein each of the interposers has side surfaces connecting the first and second surfaces thereof; disposing the interposers on a carrier through the second surfaces thereof, wherein the interposers are spaced from one another by a distance; disposing at least a semiconductor element on the first surface of each of the interposers; forming an encapsulant on the carrier for covering the side surfaces of the interposers and encapsulating the interposers and the semiconductor elements; and removing the carrier for exposing the second surfaces of the interposers from the encapsulant.

After removing the carrier, the method can further comprise performing a singulation process so as to form a plurality of semiconductor packages.

In the above-described package and method, the semiconductor element and the first ends of the conductive through holes can be electrically connected through a plurality of conductive elements.

The method can further comprise removing portions of the interposers from the second surfaces thereof for exposing the second ends of the conductive through holes. The second surfaces of the interposers and the second ends of the conductive through holes can be flush with a surface of the encapsulant.

After forming the encapsulant, the method can further comprise removing a portion of the encapsulant for exposing the surfaces of the semiconductor elements opposite to the interposers. The exposed surfaces of the semiconductor elements opposite to the interposers can be flush with a surface of the encapsulant.

After removing the carrier, the method can further comprise forming an RDL (Redistribution Layer) structure on the second surfaces of the interposers and the RDL structure is electrically connected to the second ends of the conductive through holes.

Before cutting the substrate, the method can further comprise forming an RDL structure on the first surface of the substrate and the RDL structure is electrically connected to the first ends of the conductive through holes.

Therefore, by cutting the substrate first, good interposers can be selected and rearranged so as for good semiconductor elements to be disposed thereon. As such, finished packages can be prevented from being wasted due to inferior interposers, thereby reducing the fabrication cost.

Further, since the distance between the interposers rearranged on the carrier is greater than the original distance between the interposers on the substrate, the semiconductor elements of larger size can be disposed on the interposers. Therefore, the number of the electrodes of the semiconductor elements can be increased according to the practical need so as to improve the module function and efficiency of the interposers.

### BRIEF DESCRIPTION OF DRAWINGS

FIGS. 1A to 1C are schematic cross-sectional views showing a fabrication method of a semiconductor package according to the prior art; and

FIGS. 2A to 2G are schematic cross-sectional views showing a fabrication method of a semiconductor package according to the present invention, wherein FIG. 2A′ is an upper view of FIG. 2A and FIG. 2B′ is an upper view of FIG. 2B.

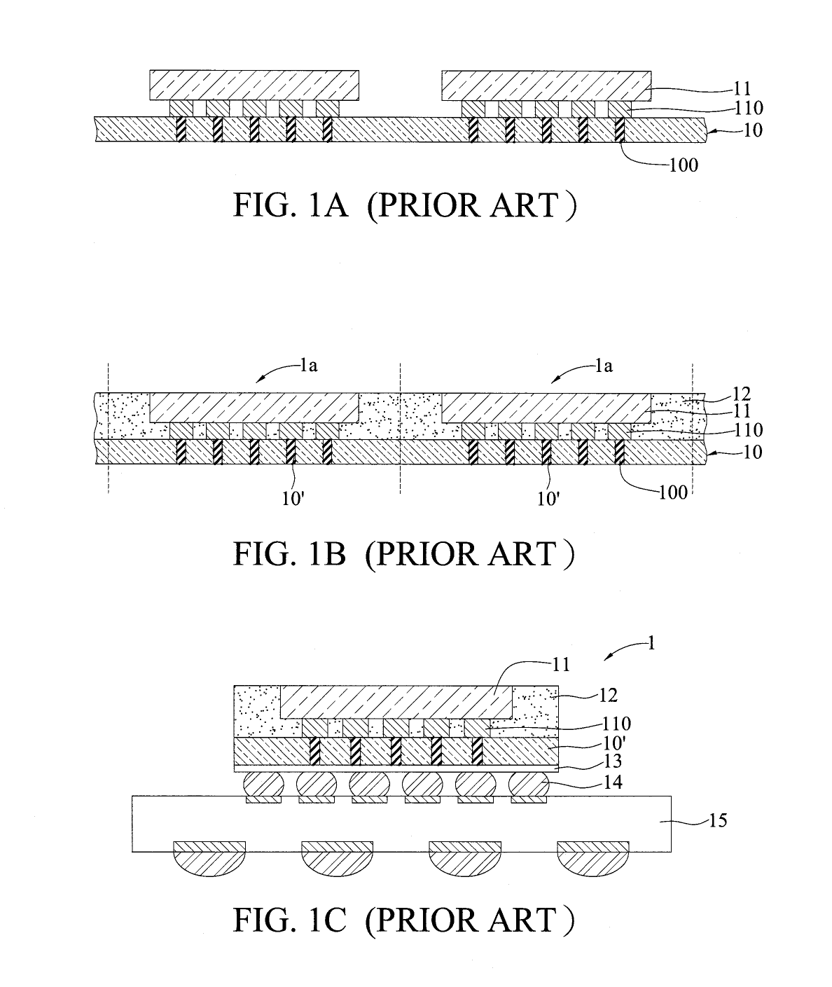

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “first”, “second”, “upper”, “lower”, “a” etc. are merely for illustrative purpose and should not be construed to limit the scope of the present invention.

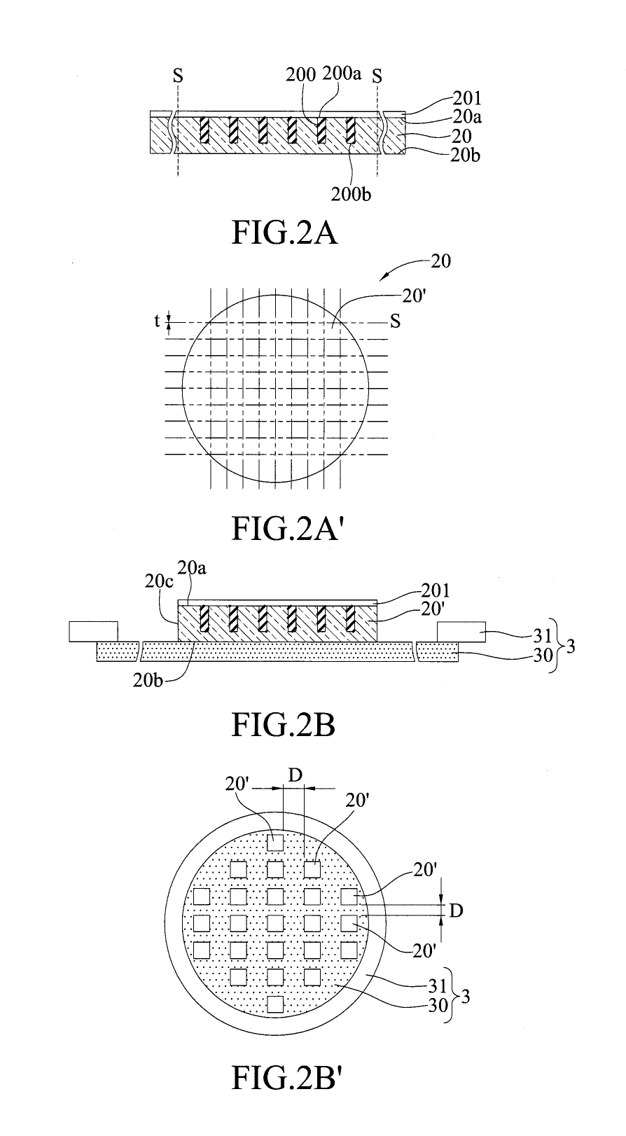

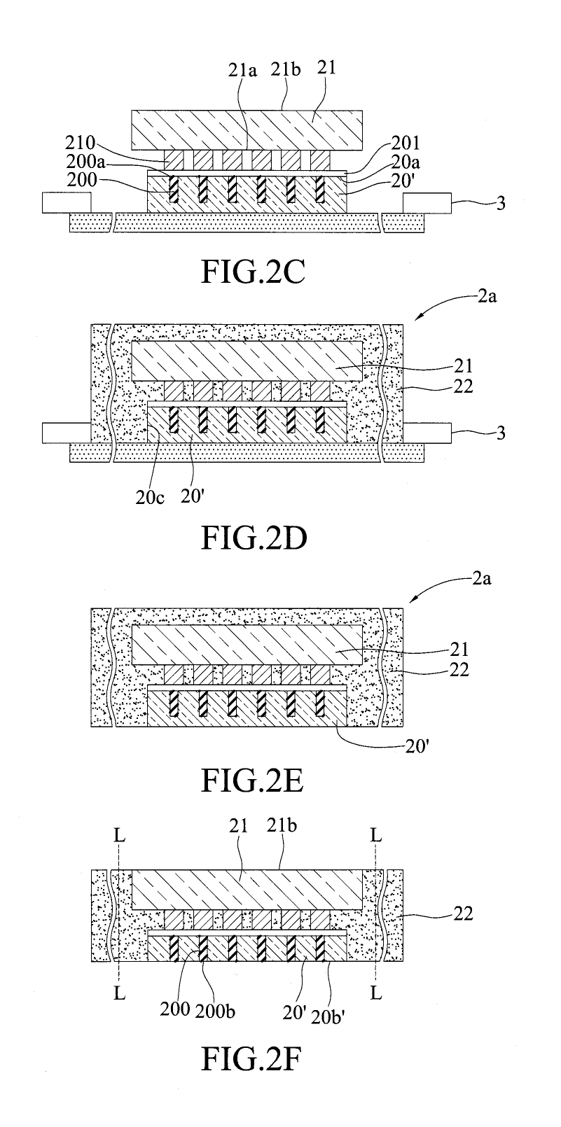

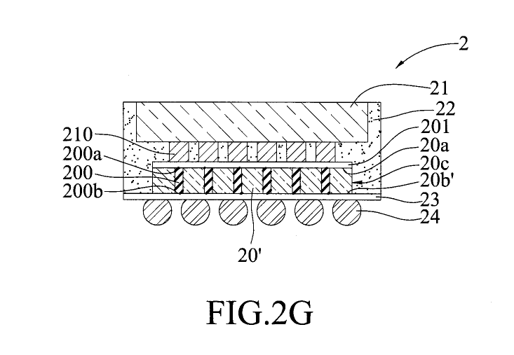

FIGS. 2A to 2G are schematic cross-sectional views showing a fabrication method of a semiconductor package 2 according to the present invention.

Referring to FIGS. 2A and 2A′, a substrate 20 having a first surface 20a and a second surface 20b opposite to the first surface 20a is provided. A plurality of conductive through holes 200 are formed in the substrate 20 and penetrating the first surface 20a. Each of the conductive through holes 200 has a first end 200a exposed from the first surface 20a of the substrate 20 and a second end 200b opposite to the first end 200a.

In the present embodiment, the substrate 20 is a wafer or made of other silicon-containing material. If needed, an RDL (Redistribution Layer) structure 201 can be formed on the first surface 20a of the substrate 20 and electrically connected to the first ends 200a of the conductive through holes 200.

Then, the substrate 20 is cut along a cutting path S so as to form a plurality of interposers 20′. Each of the interposers 20′ has side surfaces 20c connecting the first and second surfaces 20a, 20b.

Referring to FIGS. 2B and 2B′, good interposers 20′ are selected and disposed on a carrier 3 through the second surfaces 20b thereof. The interposers 20′ are spaced from one another by a distance D.

In the present embodiment, the carrier 3 has an adhesive layer 30 for bonding with the interposers 20′ and a ring body 31 surrounding an outer periphery of the adhesive layer 30.

Further, the distance D is greater than the width t of the cutting path S.

Referring to FIG. 2C, one or more semiconductor elements 21 are disposed on the first surface 20a of each of the interposers 20′.

In the present embodiment, the semiconductor elements 21 are chips. Each of the semiconductor elements 21 has an active surface 21a and an inactive surface 21b opposite to the active surface 21a, and the active surface 21a is electrically connected to the RDL structure 201 (or the first ends 200a of the conductive through holes 200) through a plurality of conductive elements 210. In particular, the active surface 21a of the semiconductor element 21 has a plurality of electrode pads (not shown) and the RDL structure 201 has a plurality of contact pads (not shown), and the electrode pads and the contact pads are connected through the conductive elements 210.

The conductive elements 210 can be bumps or posts.

Therefore, by cutting the substrate 20 first, good interposers 20′ can be selected and rearranged so as for good semiconductor elements 21 to be disposed thereon. Therefore, the present invention overcomes the conventional drawback of wasting of good semiconductor elements along with inferior interposers and reduces the fabrication cost.

Further, since the distance D between the interposers 20′ rearranged on the carrier is greater than the original distance between the interposers 20′ on the substrate 20, i.e., the width t of the cutting path S, the semiconductor elements 21 can have a size larger than the interposers 20′. Therefore, the number of the electrodes of the semiconductor elements 21 can be increased according to the practical need so as to improve the module function and efficiency of the interposers 20′.

Referring to FIG. 2D, an encapsulant 22 is formed on the carrier 3 to cover the side surfaces 20c of the interposers 20′ and encapsulate the interposers 20′ and the semiconductor elements 21, thereby forming a package 2a.

Referring to FIG. 2E, the carrier 3 is removed and the package 2a is disposed on a second carrier (not shown) through the interposers 20′.

Referring to FIG. 2F, an upper portion of the encapsulant 22 is removed by grinding for exposing the inactive surfaces 21b of the semiconductor elements 21. Then, the second carrier (not shown) is removed. Subsequently, a lower portion of the encapsulant 22 and a lower portion of the interposers 20′ are removed so as to expose the second ends 200b of the conductive through holes 200.

In the present embodiment, the second surfaces 20b′ of the interposers 20′ and the lower surface of the encapsulant 22 are flush with the second ends 200b of the conductive through holes 200, and the inactive surfaces 21b of the semiconductor elements 21 are flush with the upper surface of the encapsulant 22.

Referring to FIG. 2G, an RDL structure 23 is formed on the lower surface of the encapsulant 22 and the second surfaces 20b′ of the interposers 20′ and electrically connected to the second ends 200b of the conductive through holes 200. In another embodiment, no RDL structure is formed on the lower surface of the encapsulant 22.

Subsequently, a singulation process is performed along a cutting path L (as shown in FIG. 2F), i.e., the distance D, to thereby obtain a plurality of semiconductor packages 2.

Further, a plurality of conductive elements 24 such as solder balls can be formed on the RDL structure 24 so as for a packaging substrate (not shown) or a circuit board (not shown) to be disposed thereon.

The present invention further provides a semiconductor package 2, which has: an interposer 20′, a semiconductor element 21 disposed on the interposer 20′ and an encapsulant 22 encapsulating the interposer 20′ and the semiconductor element 21.

The interposer 20′ has opposite first and second surfaces 20a, 20b′ and side surfaces 20c connecting the opposite first and second surfaces 20a, 20b′. The interposer 20′ further has a plurality of conductive through holes 200 penetrating the first and second surfaces 20a, 20b′. Each of the conductive through holes 200 has a first end 200a exposed from the first surface 20a and a second end 200b opposite to the first end 200a.

The semiconductor element 21 has an active surface 21a and an inactive surface 21b opposite to the active surface 21a. The semiconductor element 21 is disposed on the first surface 20a of the interposer 20′ through the active surface 21a thereof and electrically connected to the first ends 200a of the conductive through holes 200 through a plurality of conductive elements 210.

The encapsulant 22 covers the side surfaces 20c of the interposer 20′ and encapsulates the interposer 20′ and the semiconductor element 21.

The semiconductor package 2 further has an RDL structure 23 formed on the second surface 20b′ of the interposer 20′ and electrically connected to the second ends 200b of the conductive through holes 200.

The semiconductor package 2 further has an RDL structure 201 formed between the semiconductor element 21 and the first surface 20a of the interposer 20′ and electrically connected to the first ends 200a of the conductive through holes 200.

In an embodiment, the second surface 20b′ of the interposer 20′ and the second ends 200b of the conductive through holes 200 are exposed from a lower surface of the encapsulant 22.

In an embodiment, the second surface 20b′ of the interposer 20′ and the lower surface of the encapuslant 22 are flush with the second ends 200b of the conductive through holes 200.

In an embodiment, the inactive surface 21b of the semiconductor element 21 is exposed from an upper surface of the encapsulant 22.

In an embodiment, the inactive surface 21b of the semiconductor element 21 is flush with the upper surface of the encapsulant 22.

Therefore, by cutting the substrate first, good interposers can be selected and rearranged so as for good semiconductor elements to be disposed thereon, thus overcoming the conventional drawback of disposing good semiconductor elements on inferior interposers and hence avoiding wasting of good semiconductor elements and reducing the fabrication cost.

Further, since the distance between the interposers rearranged on the carrier is greater than the original distance between the interposers on the substrate, the present invention allows semiconductor elements having a size larger than the interposers to be disposed on the interposers. Therefore, the number of the electrodes of the semiconductor elements can be increased according to the practical need so as to improve the module function and efficiency of the interposers.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
an interposer having opposite first and second surfaces and side surfaces connecting the opposite first and second surfaces, and a plurality of conductive through holes penetrating the first and second surfaces, wherein each of the conductive through holes has a first end exposed from the first surface and a second end opposite to the first end;
a semiconductor element disposed on the first surface of the interposer; and
an encapsulant encapsulating the interposer and the semiconductor element in a manner that the sides surfaces of the interposer are covered by the encapsulant.

2. The package of claim 1, wherein the second surface of the interposer and the second ends of the conductive through holes are exposed from the encapsulant.

3. The package of claim 1, wherein the second surface of the interposer and the second ends of the conductive through holes are flush with a surface of the encapsulant.

4. The package of claim 1, wherein a surface of the semiconductor element opposite to the interposer is exposed from the encapsulant.

5. The package of claim 4, wherein the exposed surface of the semiconductor element opposite to the interposer is flush with a surface of the encapsulant.

6. The package of claim 1, further comprising a plurality of conductive elements for electrically connecting the semiconductor element and the first ends of the conductive through holes.

7. The package of claim 1, further comprising an RDL (Redistribution Layer) structure formed on the second surface of the interposer and electrically connected to the second ends of the conductive through holes.

8. The package of claim 1, further comprising an RDL (Redistribution Layer) structure formed between the semiconductor element and the first surface of the interposer and electrically connected to the first ends of the conductive through holes.

9. A fabrication method of a semiconductor package, comprising the steps of:
providing a substrate having opposite first and second surfaces and a plurality of conductive through holes penetrating the first surface, wherein each of the conductive through holes has a first end exposed from the first surface and a second end opposite to the first end;
cutting the substrate into a plurality of interposers, wherein each of the interposers has side surfaces connecting the first and second surfaces thereof;
disposing the interposers on a carrier through the second surfaces thereof, wherein the interposers are spaced from one another by a distance;
disposing at least a semiconductor element on the first surface of each of the interposers;
forming an encapsulant on the carrier for covering the side surfaces of the interposers and encapsulating the interposers and the semiconductor elements; and
removing the carrier for exposing the second surfaces of the interposers from the encapsulant.

10. The method of claim 9, wherein the semiconductor elements and the first ends of the conductive through holes are electrically connected through a plurality of conductive elements.

11. The method of claim 9, further comprising removing portions of the interposers from the second surfaces thereof for exposing the second ends of the conductive through holes.

12. The method of claim 11, wherein the second surfaces of the interposers and the second ends of the conductive through holes are flush with a surface of the encapsulant.

13. The method of claim 9, after forming the encapsulant, further comprising removing a portion of the encapsulant for exposing surfaces of the semiconductor elements opposite to the interposers.

14. The method of claim 13, wherein the exposed surfaces of the semiconductor elements opposite to the interposers are flush with a surface of the encapsulant.

15. The method of claim 9, after removing the carrier, further comprising forming on the second surfaces of the interposers an RDL (Redistribution Layer) structure that is electrically connected to the second ends of the conductive through holes.

16. The method of claim 9, before cutting the substrate, further comprising forming on the first surface of the substrate an RDL (Redistribution Layer) structure that is electrically connected to the first ends of the conductive through holes.

17. The method of claim 9, after removing the carrier, further comprising performing a singulation process so as to form a plurality of semiconductor packages.
